(19) United States
(12) Patent Application Publication
(10) Pub. No.: US 2025/0273527 A1
(43) Pub. Date: Aug. 28, 2025

(54) SEMICONDUCTOR DEVICE, POWER CONVERSION APPARATUS, AND METHOD OF MANUFACTURING SEMICONDUCTOR DEVICE

(71) Applicant: Mitsubishi Electric Corporation, Chiyoda-ku, Tokyo (JP)

(72) Inventor: Kazunari NAKATA, Tokyo (JP)

(73) Assignee: Mitsubishi Electric Corporation, Chiyoda-ku, Tokyo (JP)

(21) Appl. No.: 18/859,403

(22) PCT Filed: May 22, 2023
(86) PCT No.: PCT/JP2023/018941

§ 371 Date: Oct. 23, 2024

(30) Foreign Application Priority Data
Jun. 22, 2022 (JP) 2022-100048

(51) Int. Cl. H01L 23/31; H01L 21/56; H10D 8/01; H10D 8/60

(52) U.S. Cl. CPC H01L 23/3171; H01L 21/56; H10D 8/051; H10D 8/60

(57) ABSTRACT

A technique disclosed in the specification of the present application is a technique for increasing reliability of a semiconductor device. A semiconductor device relating to a technique disclosed in the specification of the present application includes: a semiconductor layer; a first electrode layer covering a part of an upper surface of the semiconductor layer; and an insulating film covering another part of the upper surface of the semiconductor layer and a part of an upper surface of the first electrode layer. An arithmetic average roughness of an upper surface of the insulating film is smaller than an 10 arithmetic average roughness of an interface between the insulating film and the first electrode layer.

### TECHNICAL FIELD

A technique disclosed in the specification of the present application relates to a technique of increasing reliability of a semiconductor device.

### BACKGROUND ART

For example, a semiconductor device described in Patent Document 1, particularly a power semiconductor device such as an insulated gate bipolar transistor (IGBT), a metal-oxide-semiconductor field-effect transistor (MOSFET), or a Schottky barrier diode (SBD) is widely used as an inverter circuit of an industrial motor or an automobile motor, a power-supply apparatus of a large-capacity server, or a semiconductor switch of a permanent power-supply apparatus. In recent years, a current density of a semiconductor device is increased, thus the semiconductor device is downsized, and manufacturing cost of the semiconductor device has been reduced.

### PRIOR ART DOCUMENTS

### Patent Document(s)

Patent Document 1: Japanese Patent Application Laid-Open No. 2017-50358

### SUMMARY

### Problem to be Solved by the Invention

When the current density of the semiconductor device increases, a temperature of constituent elements in operation also increases, thus a difference of temperature increases in operation and non-operation. Thus, a detachment or a crack may occur in a protection insulating film for ensuring insulation properties of being insulated from outside the semiconductor device by stress due to thermal expansion and thermal shrinkage caused by a difference of a linear expansion coefficient of each constituent element from an electrode layer or a mold resin surrounding the protection insulating film constituting the semiconductor device. In this case, there is a problem that the insulating properties of the semiconductor device is insufficient and reliability of the semiconductor device is damaged.

The technique disclosed in the specification of the present application therefore has been made to solve problems as described above, and it is an object to provide a technique for increasing reliability of a semiconductor device.

### Means to Solve the Problem

A semiconductor device according to a first aspect of a technique disclosed in the specification of the present application includes: a semiconductor layer; a first electrode layer covering a part of an upper surface of the semiconductor layer; and an insulating film covering another part of the upper surface of the semiconductor layer and a part of an upper surface of the first electrode layer, wherein an arithmetic average roughness of an upper surface of the insulating film is smaller than an arithmetic average roughness of an interface between the insulating film and the first electrode layer.

### Effects of the Invention

According to at least the first aspect of the technique disclosed in the specification of the present application, connection to a constituent element on a lower part of a protection insulating film is more rigid than connection to a constituent element on an upper part of the protection insulating film, thus a detachment of the protection insulating film in operation can be suppressed. According to such a configuration, reliability of the semiconductor device can be increased.

These and other objects, features, aspects and advantages relating to the technique disclosed in the specification of the present application will become more apparent from the following detailed description of the present invention when taken in conjunction with the accompanying drawings.

### BRIEF DESCRIPTION OF DRAWINGS

FIG. 1 A diagram schematically illustrating an example of a configuration of a semiconductor device manufactured by a manufacturing method described in an embodiment.

FIG. 2 A diagram schematically illustrating an example of a configuration of the semiconductor device manufactured by the manufacturing method described in the embodiment.

FIG. 3 A diagram schematically illustrating an example of a configuration of the semiconductor device manufactured by the manufacturing method described in the embodiment.

FIG. 4 A flow chart illustrating an example of a process of manufacturing an SiC-SBD according to the embodiment.

FIG. 5 A cross-sectional view illustrating an example of a process of manufacturing the SiC-SBD according to the embodiment.

FIG. 6 A cross-sectional view illustrating an example of a process of manufacturing the SiC-SBD according to the embodiment.

FIG. 7 A cross-sectional view illustrating an example of a process of manufacturing the SiC-SBD according to the embodiment.

FIG. 8 A cross-sectional view illustrating an example of a process of manufacturing the SiC-SBD according to the embodiment.

FIG. 9 A cross-sectional view illustrating an example of a process of manufacturing the SiC-SBD according to the embodiment.

FIG. 10 A cross-sectional view illustrating an example of a process of manufacturing the SiC-SBD according to the embodiment.

FIG. 11 A cross-sectional view illustrating an example of a process of manufacturing the SiC-SBD according to the embodiment.

FIG. 12 A cross-sectional view illustrating an example of a process of manufacturing the SiC-SBD according to the embodiment.

FIG. 13 A diagram illustrating an enlarged configuration of a front surface electrode of the semiconductor device and a region near the protection insulating film according to the embodiment.

FIG. 14 A diagram illustrating a definition of an arithmetic average roughness.

FIG. 15 A diagram illustrating a relationship between a ratio of an arithmetic average roughness of upper and lower surfaces of the protection insulating film and a detachment rate of the protection insulating film after a power cycle test is performed one hundred thousand times.

FIG. 16 A diagram illustrating a relationship between an angle of a corner and an occurrence rate of a crack in a case there the ratio of the arithmetic average roughness of the upper and lower surfaces of the protection insulating film is 0.7 with a focus on the corner having a smallest angle in corners formed on an end portion of the upper surface of the protection insulating film.

FIG. 17 A diagram schematically illustrating an example of a configuration of the semiconductor device manufactured by the manufacturing method described in the embodiment.

FIG. 18 A diagram schematically illustrating an example of a configuration of the semiconductor device manufactured by the manufacturing method described in the embodiment.

FIG. 19 A diagram schematically illustrating an example of a configuration of the semiconductor device manufactured by the manufacturing method described in the embodiment.

FIG. 20 A flow chart illustrating an example of a process of manufacturing the SiC-SBD according to the embodiment.

FIG. 21 A cross-sectional view illustrating an example of a structure of the semiconductor device in which a process up to Step ST06 in FIG. 20 has been completed.

FIG. 22 A flow chart illustrating an example of plating preprocessing and plating processing.

FIG. 23 A flow chart illustrating a modification example of zincate processing.

FIG. 24 A flow chart illustrating a modification example of the zincate processing.

FIG. 25 A diagram illustrating an example of a structure of the semiconductor device.

FIG. 26 A diagram illustrating an example of a structure of the semiconductor device.

FIG. 27 A diagram illustrating an example of a structure of the semiconductor device.

FIG. 28 A diagram illustrating an example of a structure of the semiconductor device.

FIG. 29 A diagram illustrating a relationship between a difference between an interface of a front surface electrode-a front surface electrode and an interface of a front surface electrode-a protection insulating film and a defective rate after an assembly test.

FIG. 30 A diagram schematically illustrating a configuration of a power conversion system to which a power conversion apparatus according to the embodiment is applied.

FIG. 31 A diagram schematically illustrating an example of a configuration of the semiconductor device manufactured by the manufacturing method described in the embodiment.

FIG. 32 A diagram schematically illustrating an example of a configuration of the semiconductor device manufactured by the manufacturing method described in the embodiment.

FIG. 33 A diagram schematically illustrating an example of a configuration of the semiconductor device manufactured by the manufacturing method described in the embodiment.

### DESCRIPTION OF EMBODIMENT(S)

An embodiment is described hereinafter with reference to the accompanying diagrams. Detailed features are also described for explaining a technique in the embodiment hereinafter, however, they are only an exemplification, thus are not always necessary to be able to implement the embodiment.

The diagrams are schematically illustrated, thus omission or simplification of the configuration is performed on the diagrams for explanatory convenience. A mutual relationship of sizes and positions of configurations illustrated in the different diagram is not necessarily accurately illustrated, but can be appropriately changed. A hatching may be drawn in a plane view, for example, as well as a cross-sectional view to easily understand contents of the embodiment.

In the description hereinafter, the same reference numerals are assigned to the similar constituent elements in the illustration, and the same applies to names and functions thereof. Accordingly, the detailed description on them may be omitted to avoid a repetition in some cases.

In the description in the specification of the present application, when there is a description of “comprising”, “including”, or “having” a certain constituent element, such a description does not indicate an exclusive expression excluding the other constituent element unless otherwise noted.

In the description in the specification of the present application, even when ordinal numbers such as “first” or “second” are stated, the terms are used to facilitate understanding of embodiments, and therefore, the embodiments are not limited to an order which may be caused by the ordinal numbers.

In the description in the specification of the present application, an expression such as “. . . axis position direction” or “. . . axis negative direction” indicates that a direction along an arrow of an illustrated . . . axis is a positive direction, and a direction opposite to the arrow of the illustrated . . . axis is a negative direction.

In the description in the specification of the present application, unless otherwise noted, the expressions indicating equality such as “same”, “equal”, “uniform”, and “homogeneous”, for example, include those indicating exact equality and those in the presence of a difference within tolerance or to the extent that similar functions can be obtained.

In the description in the specification of the present application, even when terms indicating a specific position and direction such as “upper”, “lower”, “left”, “right”, “side”, “bottom”, “front” or “rear” are used, the terms are used to facilitate understanding of contents of embodiments for convenience, and therefore, irrelevant to positions or directions in practical implementation of the embodiments.

When “an upper surface of . . . ” or “a lower surface of . . . ” is described in the description in the specification of the present application, it also includes a state where the other constituent element is formed on an upper surface or a lower surface of a target constituent element in addition to the upper surface itself or the lower surface itself of the target constituent element. That is to say, when there is a description of “B provided on an upper surface of A”, for example, an intervention of the other constituent element “C” between A and B is not hindered.

### First Embodiment

A semiconductor device and a method of manufacturing the semiconductor device according to the present embodiment are described hereinafter.

### Configuration of Semiconductor Device

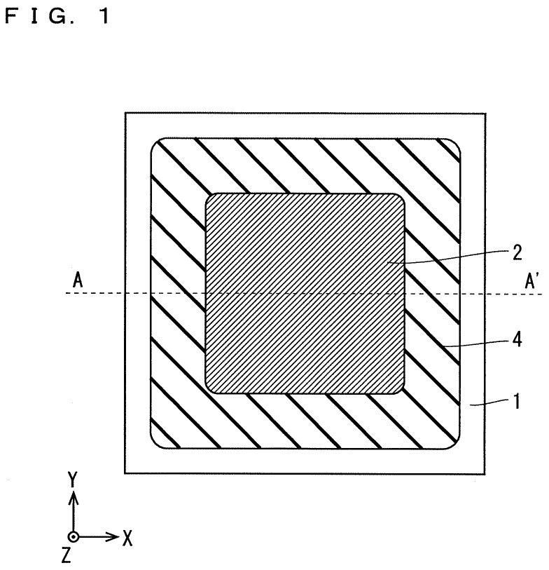

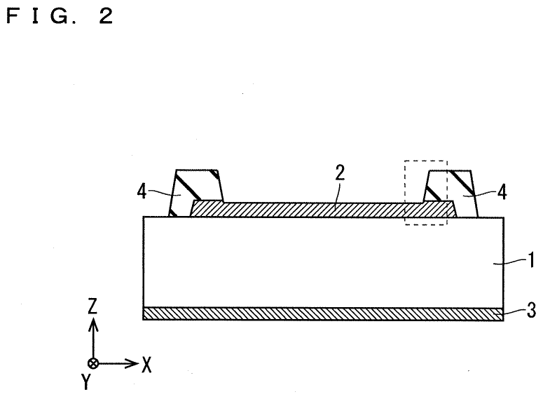

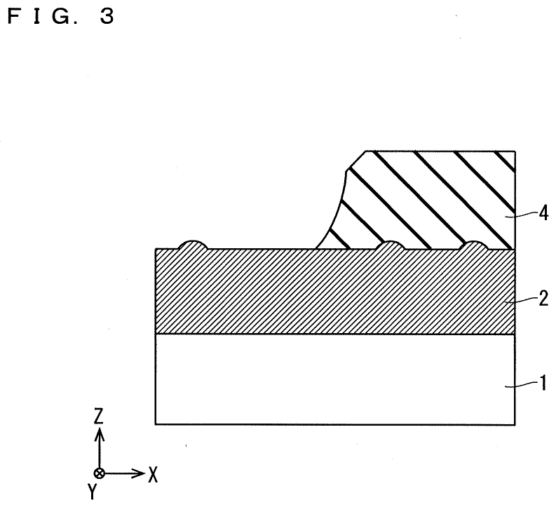

FIG. 1, FIG. 2, and FIG. 3 are diagrams each schematically illustrating an example of a configuration of a semiconductor device manufactured by a manufacturing method described in the present embodiment. FIG. 1 illustrates an example of an SiC-Schottky barrier diode (SBD).

FIG. 1 illustrates a plan view of the SiC-SBD. As illustrated in FIG. 1, a front surface electrode 2 is formed in a conductive region in a center, and formed around the front surface electrode 2 is a protection insulating film 4 for ensuring insulating properties of being insulated from a region around the front surface electrode 2.

FIG. 2 is a cross-sectional view corresponding to an A-A′ cross section illustrated by a broken line in FIG. 1. Current flows in a Z-axis direction in FIG. 2 in a front-back conductive type power semiconductor device. The front surface electrode 2 is provided to an upper surface of a semiconductor substrate 1, and a back surface electrode 3 is provided to a lower surface of the semiconductor substrate 1. Then, each of the front surface electrode 2 and the back surface electrode 3 are wired to outside by an appropriate means such as a wire or solder, for example. A protection insulating film 4 is provided to an outer peripheral part of the front surface electrode 2 to suppress an insulative defect of the semiconductor device due to electrical discharge in an outer peripheral part of a chip.

FIG. 3 is an enlarged view of a region surrounded by a broken line in FIG. 2. The front surface electrode 2 is formed on the upper surface of the semiconductor substrate 1, and furthermore, the protection insulating film 4 is formed on an upper surface of the front surface electrode 2. An arithmetic average roughness of an upper surface of the protection insulating film 4 is smaller than an arithmetic average roughness of an interface between the protection insulating film 4 and the front surface electrode 2 (that is to say, a lower surface of the protection insulating film 4). A plurality of corners are provided to an upper end of the protection insulating film 4.

### Method of Manufacturing Semiconductor Device

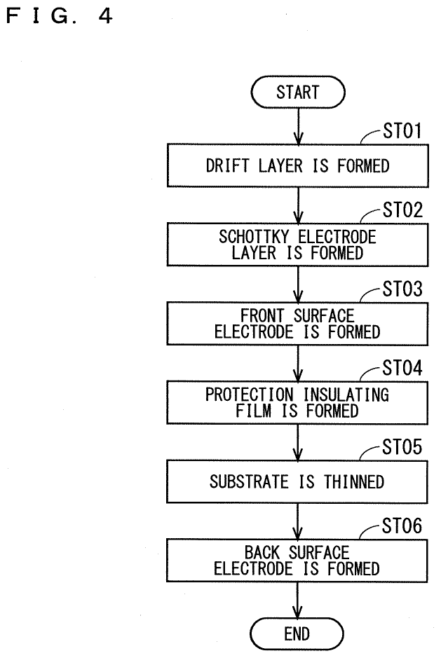

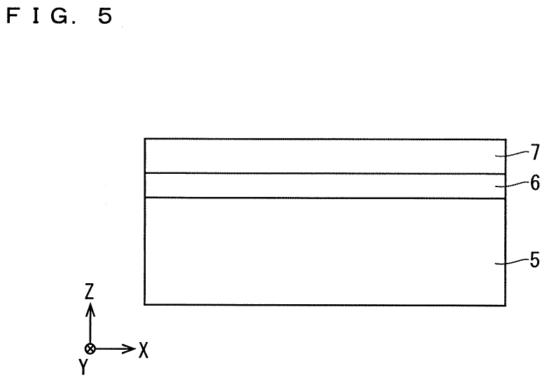

FIG. 4 is a flow chart illustrating an example of a process of manufacturing an SiC-SBD according to the present embodiment. FIG. 5 to FIG. 12 are cross-sectional views each illustrating an example of the process of manufacturing the SiC-SBD according to the present embodiment. The process of manufacturing the SiC-SBD is specifically described with reference to FIG. 5 to FIG. 12.

As illustrated in FIG. 5, after a drift layer 6 made of an n-type SiC is formed as an epitaxial film of a first layer on a first main surface (referred to as the front surface hereinafter) located on an n-type SiC substrate 5 on a side of a Z-axis positive direction, a drift layer 7 is formed as an epitaxial film of a second layer to have contact with an upper surface of the drift layer 6 by an epitaxial crystal growth method under a growth temperature lower than a growth temperature of the drift layer 6 (corresponding to Step ST01 in FIG. 4).

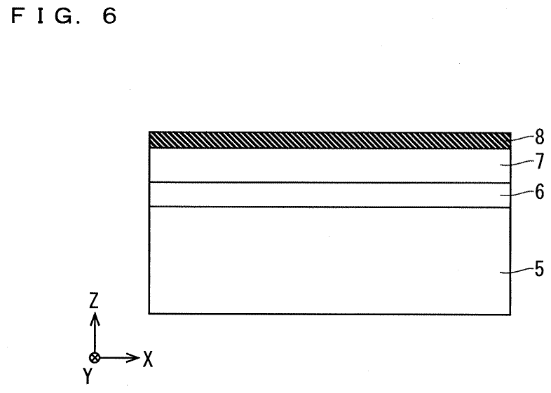

Next, as illustrated in FIG. 6, an interlayer insulating film 8 is formed on an upper surface of the drift layer 7 by a deposition method such as a thermal oxidation method or a chemical vapor deposition.

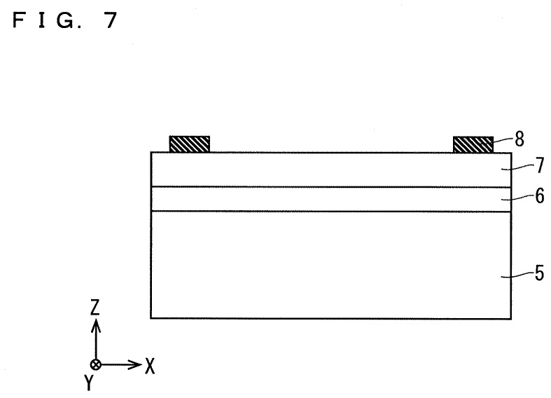

Subsequently, as illustrated in FIG. 7, after a mask made up of a resist, for example, (not shown in FIG. 7 herein) is formed using photolithography, the interlayer insulating film 8 in an unnecessary region is removed by dry etching by plasma or wet etching using a drug solution, for example, and furthermore, the mask described above is removed by plasma ashing or wet processing, for example.

In the drift layer 7 facing the interlayer insulating film 8, an impurity layer is formed by appropriately implanting and activating ions using boron (B) or aluminum (Al) as a p-type impurity and phosphorus (P) or nitrogen (N) as an n-type impurity to obtain desired withstand voltage of the SiC-SBD.

Next, wet processing using hydrofluoric acid is appropriately performed on the drift layer 7, or the drift layer 7 is appropriately washed by a compound liquid of ammonia and hydrogen peroxide water, a compound liquid of sulfuric acid and hydrogen peroxide water, or a compound liquid of hydrochloric acid and hydrogen peroxide water, and then a Schottky electrode layer 9 is formed to have contact with the drift layer 7 (corresponding to Step ST02 in FIG. 4.)

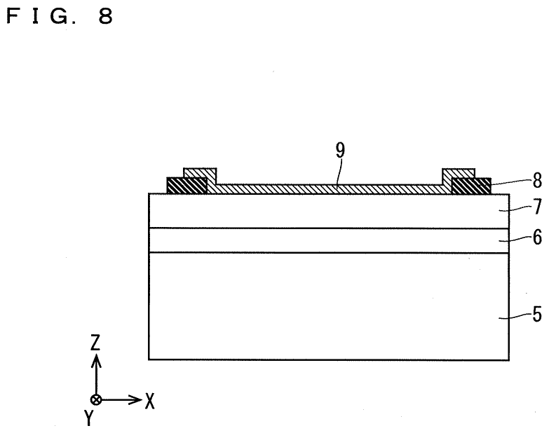

At this time, titanium (Ti), nickel (Ni), iridium (Ir), or platinum (Pt), for example, can be appropriately selected as the electrode material. Subsequently, the electrode material formed in a redundant part of the outer peripheral region is removed by patterning by photolithography and etching using plasma or a drug solution, and thermal processing is performed as necessary to reliably obtain electrical connection between the drift layer 7 and the Schottky electrode layer 9. According to such a process, a cross-sectional structure illustrated in FIG. 8 is obtained.

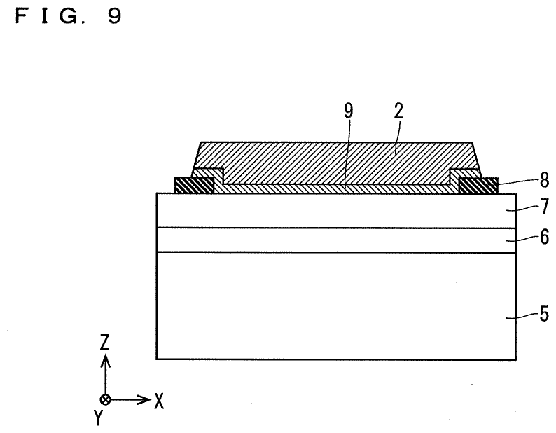

Next, as illustrated in FIG. 9, the front surface electrode 2 is formed by a sputtering method or a vapor deposition method using aluminum, aluminum alloy made of aluminum and silicon, or nickel, for example. Subsequently, the front surface electrode 2 is partially removed by patterning by photolithography and etching using plasma or a drug solution. Subsequently, concave-convex portions can be formed on a surface of the front surface electrode 2 by heating the front surface electrode 2 at a temperature equal to or higher than 150° C. and equal to or lower than 400° C. for fifteen minutes or more (corresponding to Step ST03 in FIG. 4). The front surface electrode 2 is formed on a part of upper surfaces of the drift layer 6 and the drift layer 7 via the Schottky electrode layer 9 and the interlayer insulating film 8, for example.

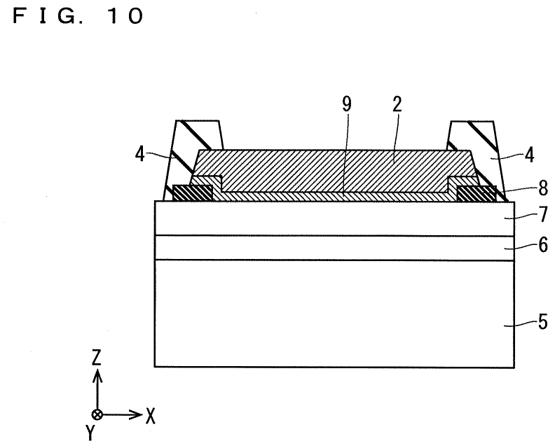

Subsequently, the protection insulating film 4 is formed as illustrated in FIG. 10. Polyimide or silicone resin is preferable as a material of the protection insulating film 4, and the protection insulating film 4 is formed on an outermost peripheral on a side of a surface of the SiC-SBD by using spin coating, photolithography, and an etching technique or using an application technique by ink jet (corresponding to Step ST04 in FIG. 4). The protection insulating film 4 covers a part of the upper surface of the drift layer 7 which is not covered by the front surface electrode 2. The protection insulating film 4 covers a part of the upper surface of the front surface electrode 2.

After the protection insulating film 4 is formed, a plurality of corners are formed on an upper surface of the protection insulating film 4 by surface processing using plasma including oxygen and argon. At that time, when a plurality of corners are also formed on the upper surface of the protection insulating film 4 on a side of an outer periphery of the semiconductor device, reliability is further improved.

A favorable processing method such as repetitive operation of an application technique by ink jet and thermal processing subsequently performed at a temperature of 250° C. or more can be appropriately selected as a method of forming the plurality of comers on the upper surface (upper end) of the protection insulating film 4.

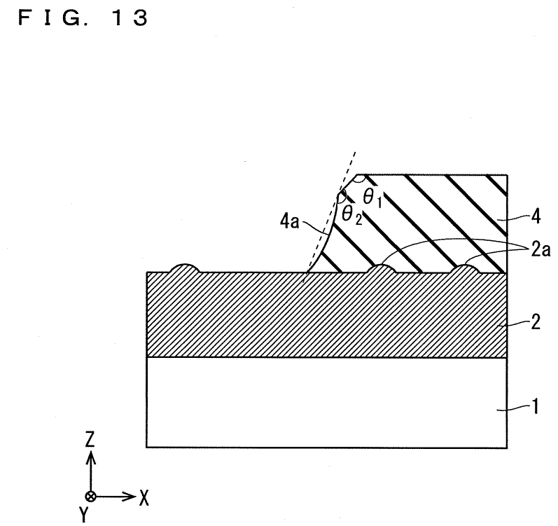

Next, an inclined surface of the protection insulating film 4 is formed into an arc-like shape as exemplified in FIG. 13 hereinafter by performing thermal processing at a temperature equal to or higher than 200° C. and equal to or lower than 400° C., more preferably, equal to or higher than 250° C. and equal to or lower than 380° C., for example. The above thermal processing after the front surface electrode 2 is formed can double as thermal processing after the protection insulating film 4 is formed.

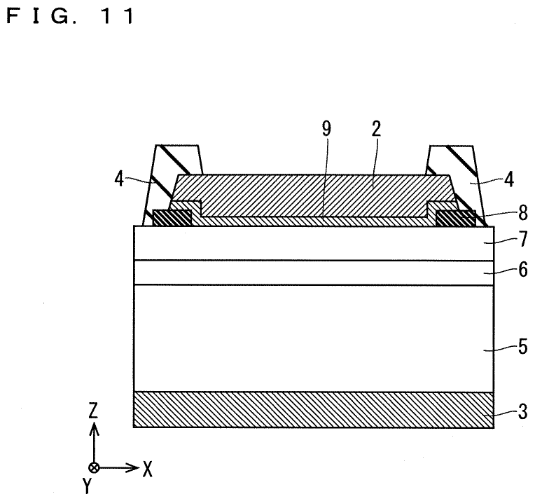

Subsequently, as illustrate in FIG. 11, the SiC substrate 5 is thinned (reduced in thickness) from a side of a lower surface of the SiC substrate 5 to reduce loss in power conduction by mechanical processing using an abrasive wheel made up of alumina abrasive grains or diamond abrasive grains, for example (corresponding to Step ST05 in FIG. 4). Thinning (reduction in thickness) of SiC substrate 5 can be omitted as necessary.

Subsequently, the back surface electrode 3 is formed using titanium, titanium alloy, aluminum, aluminum alloy made of aluminum and silicon, or nickel, for example (corresponding to Step ST06 in FIG. 4). As for the back surface electrode 3, an antioxidation film made of gold, platinum, silver, or silver alloy including palladium, for example, may be formed on an outermost surface of the back surface electrode 3 in soldering to prevent oxidation of the electrode material.

Subsequently, the member thereby made is diced using a dicing device to obtain the semiconductor device exemplified in FIG. 1, FIG. 2, and FIG. 3 for the plurality of semiconductor devices formed in the semiconductor wafer.

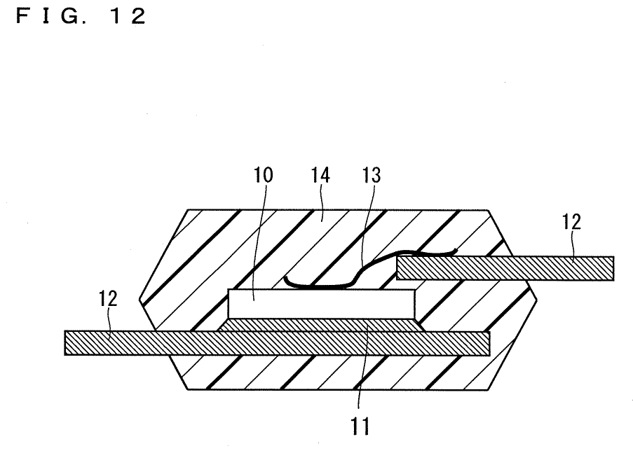

Then, as exemplified in FIG. 12, an upper surface and a lower surface of a semiconductor device 10 are connected to a lead frame 12 using a solder 11 and a wire 13, respectively, and then sealed by a mold resin 14, thus a semiconductor module is completed.

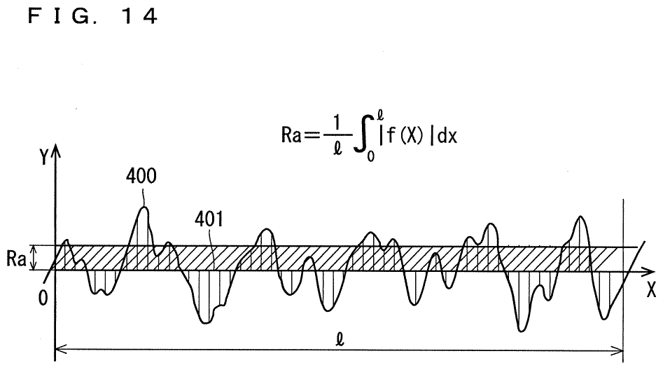

FIG. 13 is diagram illustrating an enlarged configuration of the front surface electrode 2 of the semiconductor device 10 and a region near the protection insulating film 4 according to the present embodiment. FIG. 14 is a diagram illustrating a definition of an arithmetic average roughness. As illustrated in FIG. 14, according to a definition of surface roughness (JIS B 0601:1994, JIS B 0031:1994), an arithmetic average roughness Ra can be obtained by an expression in FIG. 14 in which a reference length is extracted from a roughness curve 400 in a direction of an average line 401, the direction of the average line of this extracted part is set to an X axis, and a direction of a vertical magnification is set to a Y axis.

The inventors performs line scan of 1 mm using an atomic force microscope (AFM) of SPM-9600 manufactured by SHIMADZU CORPORATION to obtain the roughness curve 400 described above, and then calculates the arithmetic average roughness Ra. A method of calculating the arithmetic average roughness Ra is not limited thereto described above, however, an optional method such as a stylus type level difference-surface roughness meter or a laser microscope which can perform non-contact measurement can be selected, for example.

In FIG. 13, the arithmetic average roughness of the upper surface of the protection insulating film 4 is smaller than that of the interface between the protection insulating film 4 and the front surface electrode 2 (that is to say, the lower surface of the protection insulating film 4). A plurality of convex parts 2a are formed on the upper surface of the front surface electrode 2 in FIG. 13, and these convex parts 2a cause increase of the arithmetic average roughness at the interface between the protection insulating film 4 and the front surface electrode 2.

A plurality of corners are formed on an end portion of the upper surface of the protection insulating film 4 in FIG. 13. Specifically, the end portion of the upper surface of the protection insulating film 4 constitutes an inclined surface, a corner formed on an upper end of the inclination surface has an angle θ₁, and a corner formed on a lower end of the inclination surface has an angle θ₂.

An edge line 4a of a side surface of the protection insulating film 4 has a concave shape compared with a straight line drawn from the end portion of the upper surface (specifically, a corner formed on a lower end of the inclined surface) to an end portion of the lower surface (corner).

The inventors have performed a power cycle test repeating a conduction state and a non-conduction state of the semiconductor device on the semiconductor module having the structure illustrated in FIG. 12.

The protection insulating film 4 receives stress due to thermal expansion and thermal shrinkage caused by a difference of a linear expansion coefficient from the mold resin 14 from a side of the upper surface and a difference of a linear expansion coefficient from the front surface electrode 2 from a side of the lower surface.

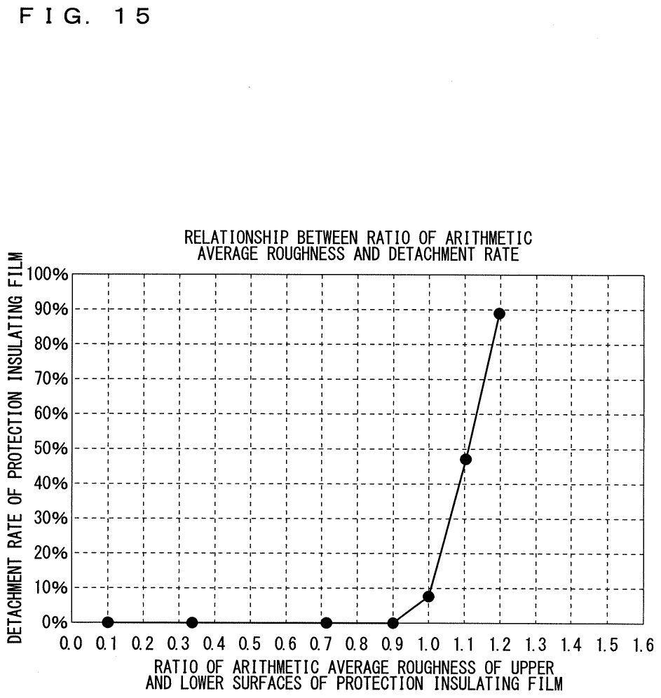

FIG. 15 is a diagram illustrating a relationship between a ratio of the arithmetic average roughness of the upper and lower surfaces of the protection insulating film 4 and a detachment rate of the protection insulating film 4 after the power cycle test is performed one hundred thousand times. In FIG. 15, a vertical axis indicates the detachment rate of the protection insulating film 4, and a lateral axis indicates the ratio of the arithmetic average roughness of the upper and lower surfaces of the protection insulating film 4 (the arithmetic average roughness of the upper surface/the arithmetic average roughness of the lower surface).

According to FIG. 15, when the ratio of the arithmetic average roughness of the upper and lower surfaces of the protection insulating film 4 (the arithmetic average roughness of the upper surface/the arithmetic average roughness of the lower surface) is equal to or smaller than 0.9, sticking force between the protection insulating film 4 and the front surface electrode 2 can be sufficiently achieved with respect to the stress on the protection insulating film 4 received from the mold resin 14. Thus, detachment of the protection insulating film 4 can be suppressed.

When the semiconductor module after the above test is performed is opened and analyzed, it is confirmed that a crack occurs in a corner part having an acutest angle in the protection insulating film 4.

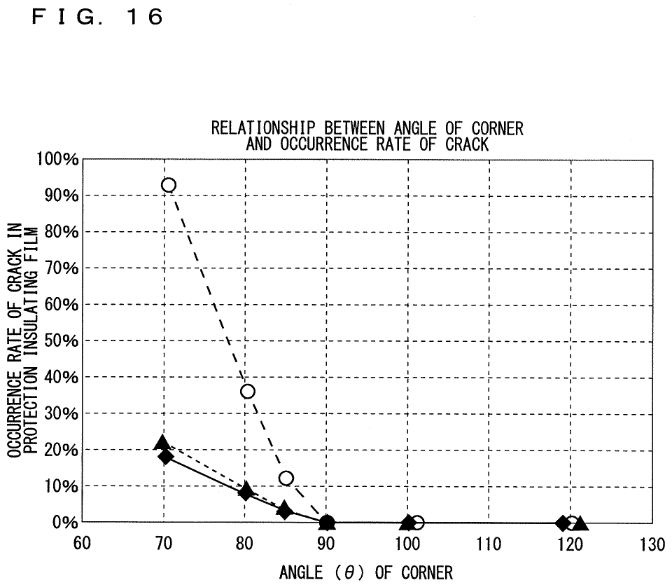

FIG. 16 is a diagram illustrating a relationship between an angle of the corner and an occurrence rate of a crack in the above power cycle test in a case there the ratio of the arithmetic average roughness of the upper and lower surfaces of the protection insulating film 4 (the arithmetic average roughness of the upper surface/the arithmetic average roughness of the lower surface) is 0.7 with a focus on the corner having a smallest angle in the corners formed on an end portion of the upper surface of the protection insulating film 4. In FIG. 16, a vertical axis indicates the occurrence rate of the crack in the protection insulating film 4, and a lateral axis indicates an angle [θ] of the corner having the smallest angle in the corners formed on the end portion of the upper surface of the protection insulating film 4. In FIG. 16, a case where the number of corners described above is one (that is to say, only the corner having the smallest angle) is expressed by white circle marks, a case where the number of the corners described above is two is expressed by black triangle marks, and a case where the number of corners described above is three is expressed by black squares marks.

Recognized from FIG. 16 is that the angle of the corner formed on the end portion of the upper surface of the protection insulating film 4 is 90 degrees or more, thus the stress received from the mold resin 14 can be reduced. It is also recognized that the plurality of corners are formed on the end portion of the upper surface of the protection insulating film 4, thus the crack occurring in the protection insulating film 4 can be reduced.

Recognized by verification by the inventors is that as exemplified in FIG. 13, when the edge line 4a of the side surface of the protection insulating film 4 retracts (has the concave shape) with respect to the straight line drawn from the corner of the upper surface of the protection insulating film 4 to the corner of the lower surface, a favorable effect of suppressing the crack in the protection insulating film 4 is achieved.

### Second Embodiment

A semiconductor device and a method of manufacturing the semiconductor device relating to the present embodiment are described. In the description hereinafter, the same reference numerals as those described in the above embodiment will be assigned to the similar constituent elements in the diagrams, and detailed description thereof is appropriately omitted.

### Configuration of Semiconductor Device

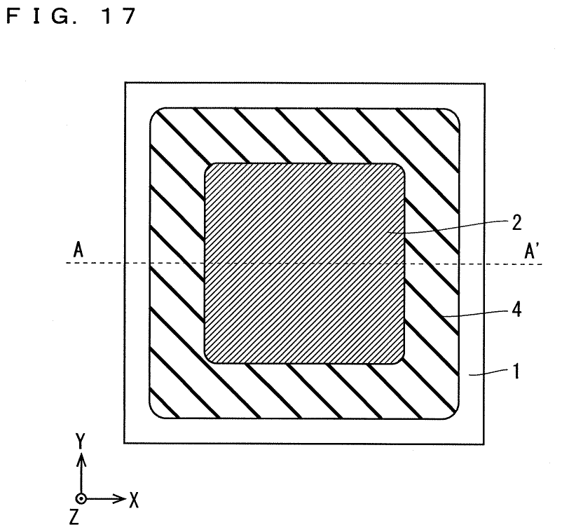

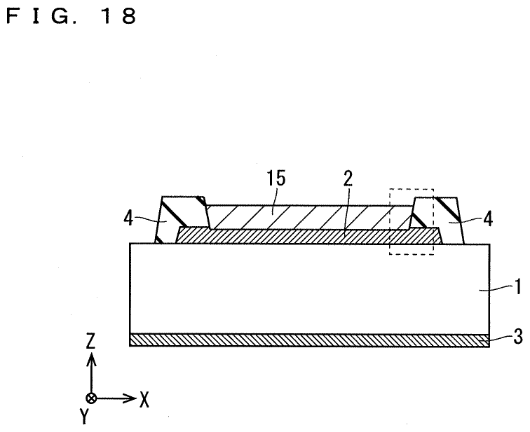

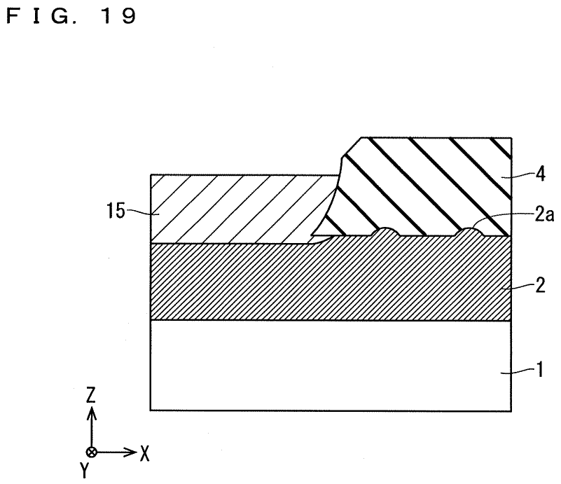

FIG. 17, FIG. 18, and FIG. 19 are diagrams each schematically illustrating an example of a configuration of a semiconductor device manufactured by a manufacturing method described in the present embodiment. FIG. 1 illustrates an example of an SiC-Schottky barrier diode (SBD).

FIG. 17 illustrates a plan view of the SiC-SBD. As illustrated in FIG. 17, the front surface electrode 2 is formed in a conductive region in a center, and formed around the front surface electrode 2 is the protection insulating film 4 for ensuring insulating properties of being insulated from a region around the front surface electrode 2. FIG. 17 is different from FIG. 1 in that a front surface electrode 15 is formed to cover a part of the upper surface of the front surface electrode 2.

FIG. 18 is a cross-sectional view corresponding to an A-A′ cross section illustrated by a broken line in FIG. 17. Current flows in a Z-axis direction in FIG. 18 in a front-back conductive type power semiconductor device. In FIG. 18, the front surface electrode 15 is formed compared with the configuration illustrated in FIG. 2, thus a wire can be connected to an outer part using solder on a side of an upper surface of the power semiconductor device, and such a configuration can also deal with conduction of large current.

FIG. 19 is an enlarged view of a region surrounded by a broken line in FIG. 18. The front surface electrode 2 is formed on the upper surface of the semiconductor substrate 1, and furthermore, the protection insulating film 4 and the front surface electrode 15 are formed on the upper surface of the front surface electrode 2. The arithmetic average roughness of the upper surface of the protection insulating film 4 is smaller than that of the interface between the protection insulating film 4 and the front surface electrode 2. The plurality of corners are provided to the upper end of the protection insulating film 4. The interface between the front surface electrode 2 and the front surface electrode 15 is located on a lower side than the interface between the front surface electrode 2 and the protection insulating film 4.

### Method of Manufacturing Semiconductor Device

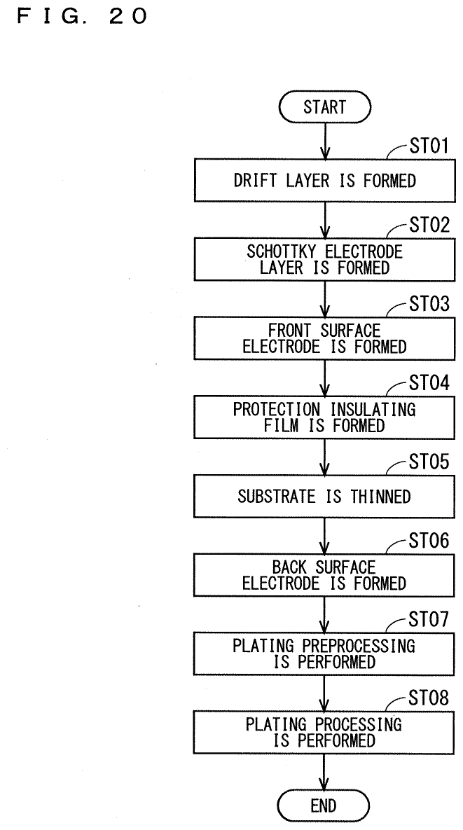

FIG. 20 is a flow chart illustrating an example of a process of manufacturing an SiC-SBD according to the present embodiment. FIG. 5 to FIG. 12 are cross-sectional views each illustrating an example of the process of manufacturing the SiC-SBD according to the present embodiment. The process of manufacturing the SiC-SBD is specifically described with reference to FIG. 5 to FIG. 12.

Step ST01 to Step ST06 in FIG. 20 have contents similar to Step ST01 to Step ST06 in FIG. 4, thus the description is omitted.

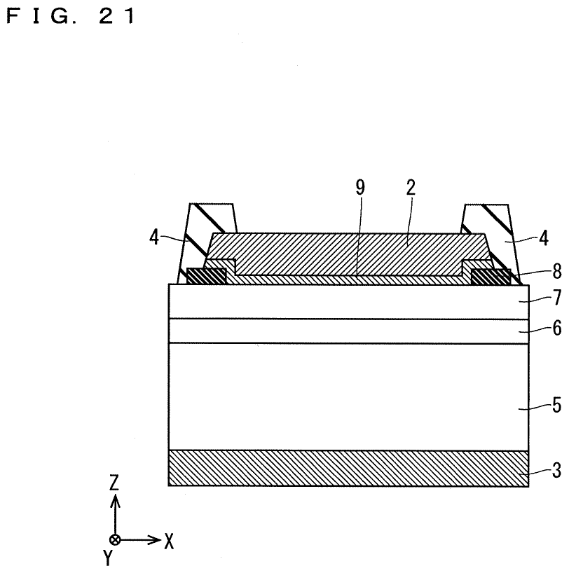

FIG. 21 is a cross-sectional view illustrating an example of a structure of the semiconductor device in which a process up to Step ST06 in FIG. 20 has been completed.

Next, an electrode is formed using a plating method on a surface of the semiconductor device (corresponding to Step ST07 and Step ST08 in FIG. 20). Even when the plating processing is performed on an Al electrode or an Al alloy electrode on the wafer after commonly known degreasing and pickling are performed, a firm organic residue and an oxide film are formed on the surface of the Al or Al alloy on the wafer (Al or Al alloy is also referred to as Al alloy hereinafter), thus a metal diffusion does not occur between the Al alloy and the plating metal, and a plating layer with firm sticking force cannot be formed.

Thus, in the present process, plasma cleaning, degreasing, acid cleaning, zincate processing, and plating are performed in this order for the plating processing on the Al alloy electrode on the wafer. It is necessary to ensure a sufficient time for water washing between each of the processes to prevent a processing solution or a residue in the previous process from being introduced in the next process.

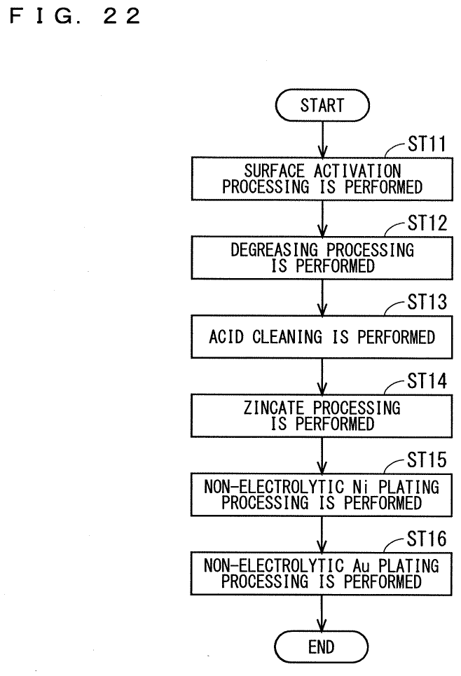

An outline of the plating preprocessing and plating processing is described hereinafter with reference to FIG. 22. Herein, FIG. 22 is a flow chart illustrating an example of the plating preprocessing and the plating processing.

Firstly, surface activation processing as the plating preprocessing is performed using plasma, for example (corresponding to Step ST11 in FIG. 22). Herein, the plasma cleaning using plasma is processing of cleaning the surface of the Al alloy electrode by oxidation-decomposing or beating out an organic residue which is baked on the Al alloy electrode and cannot be removed by general plating preprocessing using plasma.

Next, degreasing processing and acid cleaning are performed as the plating preprocessing (corresponding to Step ST12 and Step ST13 in FIG. 22). The decreasing processing is processing performed for removing light organic contamination or an oxide film remaining on the Al alloy surface. The acid cleaning is processing of neutralizing the Al alloy surface, further etching and roughening the surface of the Al alloy to increase reactivity of a processing solution in the subsequent processing, and improving sticking force of plating.

Next, zincate processing is performed as the plating preprocessing (corresponding to Step ST14 in FIG. 22). Subsequently, the plating processing is performed to form a plating film having firm sticking force. Specifically, after non-electrolytic Ni plating processing is performed, non-electrolytic Au plating processing is performed (corresponding to Step ST15 and Step ST16 in FIG. 22).

The zincate processing is described herein. The zincate processing is processing of forming a film of zinc (Zn) on the surface of the Al alloy while removing the oxide film of Al. Specifically, when the Al alloy is immersed in a water solution in which Zn is dissolved as ions, Al is dissolved as ions by reason that Zn has nobler reference oxidation-reduction potential than Al. Then, Zn ions receive electrons at the surface of the Al alloy by the electrons occurring at this time, and a film of Zn is formed on the surface of Al. An oxide film of Al is also removed at this time.

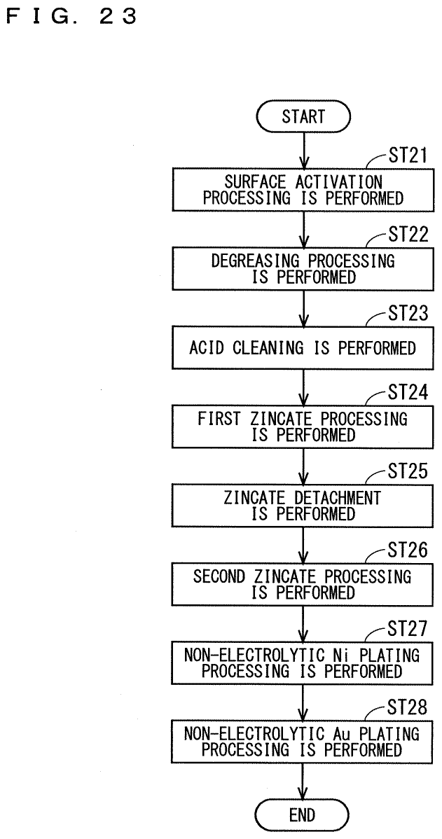

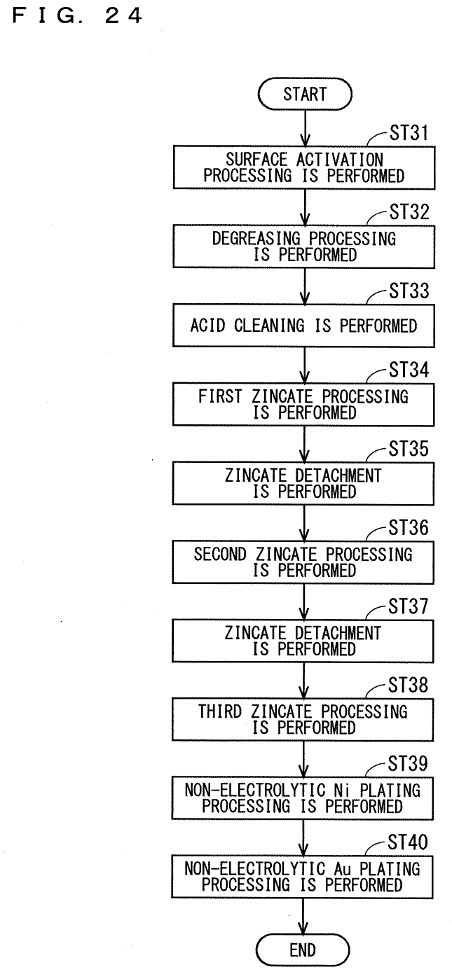

FIG. 23 and FIG. 24 are flow charts each illustrating a modification example of the zincate processing.

In FIG. 23, surface activation processing such as plasma cleaning is performed firstly (corresponding to Step ST21 in FIG. 23). Next, degreasing processing and acid cleaning are performed (corresponding to Step ST22 and Step ST23 in FIG. 23).

Next, first zincate processing is performed (corresponding to Step ST24 in FIG. 23). Then, after zincate detachment (corresponding Step ST25 in FIG. 23) is performed, second zincate processing is performed again (corresponding to Step ST26 in FIG. 23).

Subsequently, the plating processing is performed to form a plating film having firm sticking force. Specifically, after non-electrolytic Ni plating processing is performed, non-electrolytic Au plating processing is performed (corresponding to Step ST27 and Step ST28 in FIG. 23).

In FIG. 24, surface activation processing such as plasma cleaning is performed firstly (corresponding to Step ST31 in FIG. 24). Next, degreasing processing and acid cleaning are performed (corresponding to Step ST32 and Step ST33 in FIG. 24).

Next, first zincate processing is performed (corresponding to Step ST34 in FIG. 24). Then, after zincate detachment (corresponding Step ST35 in FIG. 24) is performed, second zincate processing is performed again (corresponding to Step ST36 in FIG. 24). Then, after zincate detachment (corresponding Step ST37 in FIG. 24) is performed, third zincate processing is performed again (corresponding to Step ST38 in FIG. 24).

Subsequently, the plating processing is performed to form a plating film having firm sticking force. Specifically, after non-electrolytic Ni plating processing is performed, non-electrolytic Au plating processing is performed (corresponding to Step ST39 and Step ST40 in FIG. 24).

As exemplified in FIG. 23 and FIG. 24, when the zincate processing and the zincate detachment are repetitively performed, the Al alloy covered by Zn is immersed in concentrated nitric acid and Zn is dissolved, and then a thin uniform Al oxide film is formed on the surface of Al. Then, the Al alloy is immersed in the Zn processing solution again and a surface of the Al alloy is covered by Zn, and furthermore, the oxide film of Al is removed.

According to such an operation, the oxide film layer on the surface of the Al alloy is thinned and smoothed. As the number of operations described above increases, the surface of Al is uniformed, and performance of the plating film is improved, however, when productivity is taken into consideration, it is preferable to perform the zincate processing illustrated in FIG. 23 twice or perform the zincate processing illustrated in FIG. 24 three times.

In this manner, the zincate processing and the zincate detachment are performed three times at most, thus the interface can be formed so that the interface between the front surface electrode 2 and the front surface electrode 15 is located on a lower side than the interface between the front surface electrode 2 and the protection insulating film 4. When such an interface located on the lower side is formed, the surface activation processing (corresponding to Step ST11) illustrated in FIG. 22 can also be applied together.

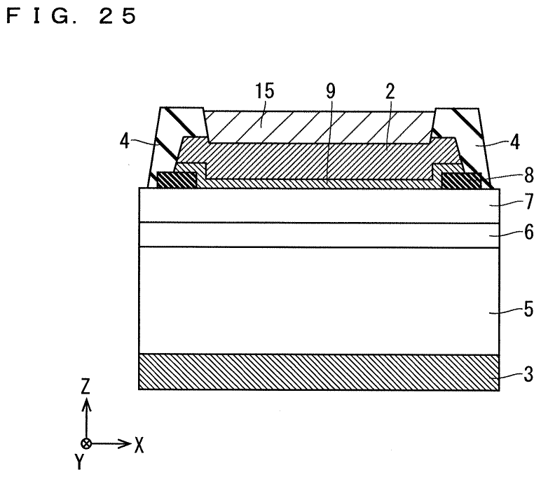

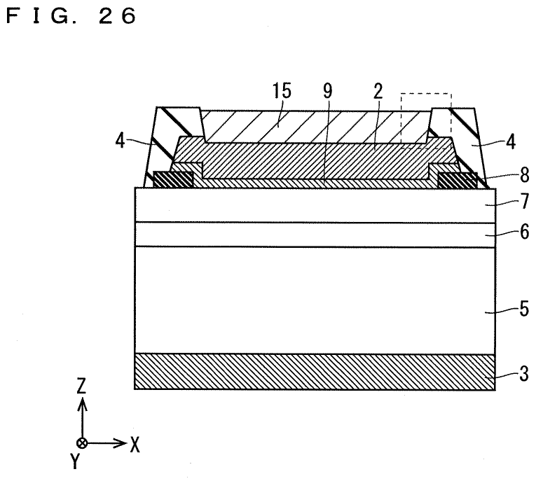

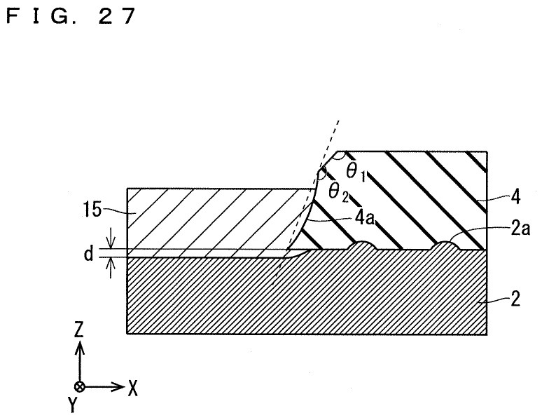

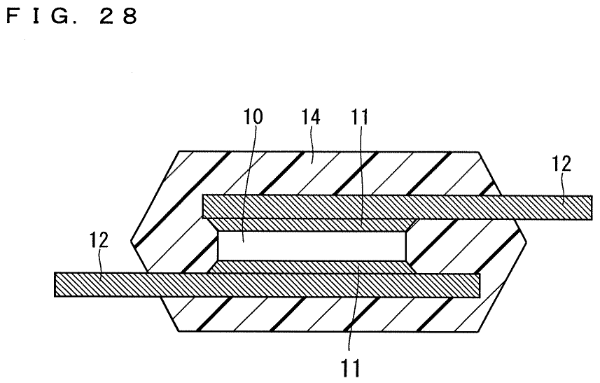

FIG. 25, FIG. 26, FIG. 27, and FIG. 28 are diagrams each illustrating an example of a structure of a semiconductor device manufacture by the flow described above. FIG. 27 is an enlarged view of a region surrounded by a broken line in FIG. 26. In FIG. 27, a distance from the interface between the protection insulating film 4 and the front surface electrode 2 as a reference surface to the interface between the front surface electrode 15 and the front surface electrode 2 located on the lower side than the reference surface is defined as d.

Then, the inventors have performed an assembly test of a semiconductor module in which each of the upper surface and the lower surface of the semiconductor device 10 are bonded to the lead frame 12 via the solder 11, and are further sealed by the mold resin 14 as exemplified in FIG. 28.

In the assembly test described above, as an acceleration test, a soldering process is repeated three times to further apply more stress from the front surface electrode 2, the front surface electrode 15, the solder 11, or the lead frame 12 to the protection insulating film 4.

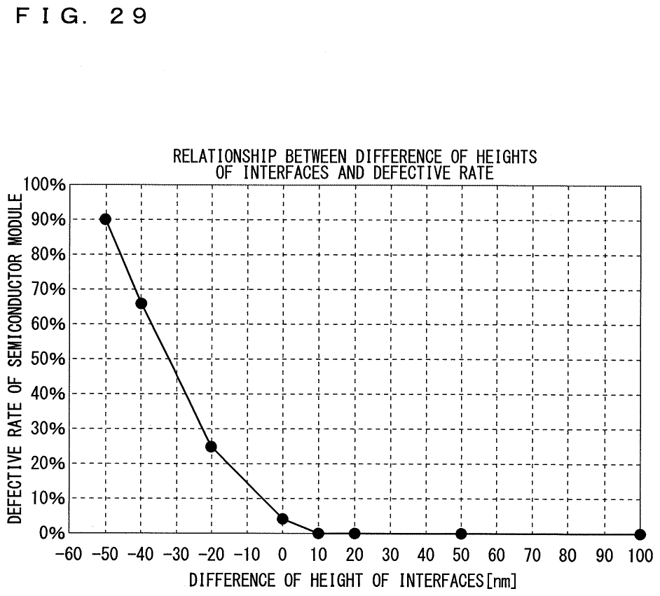

FIG. 29 is a diagram illustrating a relationship between a difference between the interface of the front surface electrode 2−the front surface electrode 15 and the interface of the front surface electrode 2−the protection insulating film 4 and a defective rate after the assembly test. In FIG. 29, a vertical axis indicates the defective rate of the semiconductor module after the assembly test, and a lateral axis indicates the difference between the interface of the front surface electrode 2−the front surface electrode 15 and the interface of the front surface electrode 2−the protection insulating film 4. In FIG. 29, a part where the vertical axis indicates a minus value indicates that the interface of the front surface electrode 2−the front surface electrode 15 protrudes with respect to interface of the front surface electrode 2−the protection insulating film 4.

According to FIG. 29, when the difference between the interface of the front surface electrode 2−the front surface electrode 15 and the interface of the front surface electrode 2−the protection insulating film 4 is equal to or larger than 10 nm, the defective rate of the semiconductor module after the assembly test can be suppressed.

When the semiconductor module having a defect after the assembly test described above is analyzed, it is recognized that an insulative defect occurs due to detachment of the protection insulating film 4. Thus, it is considered that when the interface of the front surface electrode 2−the front surface electrode 15 is located on the lower side than the interface of the front surface electrode 2−the protection insulating film 4, the stress on the protection insulating film 4 is reduced, and the defective rate of the semiconductor module after the assembly test is suppressed.

### Third Embodiment

Described are a power conversion apparatus and a method of manufacturing the power conversion apparatus according to the present embodiment. In the description hereinafter, the same reference numerals as those described in the above embodiment will be assigned to the similar constituent elements in the diagrams, and detailed description thereof is appropriately omitted.

### Configuration of Power Conversion Apparatus

The semiconductor device according to the first embodiment and the second embodiment is applied to a power conversion apparatus in the present embodiment. The power conversion apparatus according to the present embodiment is not limited to a specific power conversion apparatus, however, described hereinafter is a case where the power conversion apparatus according to the present embodiment is applied to a three-phase inverter.

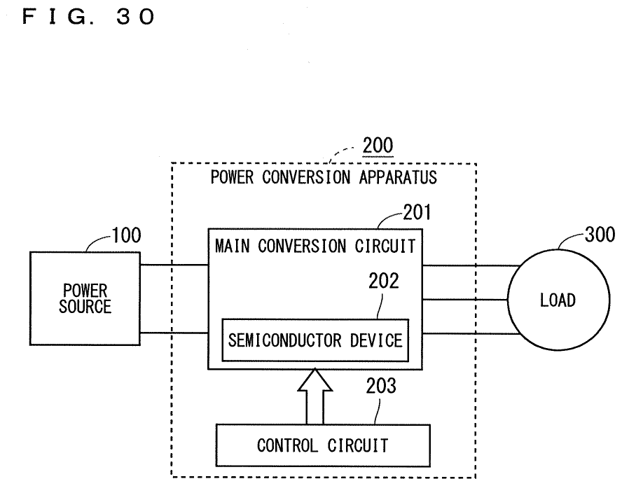

FIG. 30 is a diagram schematically illustrating a configuration of a power conversion system to which a power conversion apparatus 200 according to the present embodiment is applied. A power conversion system illustrated in FIG. 30 includes a power source 100, a power conversion apparatus 200, and a load 300.

The power source 100 is a direct current power source, and supplies direct current power to the power conversion apparatus 200. The power source 100 can be made up of various power sources, thus may be made up of a direct current system, a solar battery, or a storage battery, for example, and may also be made up of a rectification circuit connected to an alternating current system or an AC/DC converter. The power source 100 may also be made up of a DC/DC converter converting direct current power being output from a direct current system into predetermined power.

The power conversion apparatus 200 is a three-phase inverter connected between the power source 100 and the load 300. The power conversion apparatus 200 converts direct current power supplied from the power source 100 into alternating current power, and supplies the direct current power to the load 300. The power conversion apparatus 200 includes a main conversion circuit 201 and a control circuit 203. The main conversion circuit 201 converts the direct current power which has been inputted into alternating current power, and outputs the alternating current power. The control circuit 203 outputs a control signal for controlling the main conversion circuit 201 to the main conversion circuit 201.

The load 300 is a three-phase electrical motor driven by the alternating current power supplied from the power conversion apparatus 200. The load 300 is not for a specific purpose of usage, but is an electrical motor mounted on various types of electrical apparatuses, thus is used as an electrical motor for a hybrid automobile, an electrical automobile, a railroad vehicle, an elevator, or an air-conditioning machine, for example.

Details of the power conversion apparatus 200 are described hereinafter. The main conversion circuit 201 includes a switching element and a reflux diode (not shown herein). When the switching element is switched, the main conversion circuit 201 converts the direct current power supplied from the power source 100 into the alternating current power, and supplies the alternating current power to the load 300. Examples of a specific circuit configuration of the main conversion circuit 201 include various configurations, however, the main conversion circuit 201 according to the present embodiment is a three-phase full-bridge circuit with two levels, and can be made up of six switching elements and six reflux diodes antiparallelly connected to each switching element. The semiconductor device 202 according to any of the first embodiment, the second embodiment, and the modification example thereof described above is applied to at least one of the switching element and the reflux diode of the main conversion circuit 201. Six switching elements are connected two by two in series to constitute upper and lower arms, and each pair of the upper and lower arms constitutes each phase (U phase, V phase, and W phase) of a full-bridge circuit. Output terminals of the pair of the upper and lower arms, that is to say, three output terminals of the main conversion circuit 201 are connected to the load 300.

The main conversion circuit 201 includes a drive circuit (not shown) driving each switching element. The drive circuit generates a drive signal for driving the switching element of the main conversion circuit 201, and supplies the drive signal to a control electrode of the switching element of the main conversion circuit 201. Specifically, the drive circuit outputs a drive signal for making the switching element enter an ON state and a drive signal for making the switching element enter an OFF state to a control electrode of each switching element in accordance with a control signal from the control circuit 203 describe hereinafter. When the switching element is kept in the ON state, the drive signal is a voltage signal (ON signal) equal to or larger than threshold voltage of the switching element, and when the switching element is kept in the OFF state, the drive signal is a voltage signal (OFF signal) equal to or smaller than the threshold voltage of the switching element.

The control circuit 203 controls the switching element of the main conversion circuit 201 so that desired electrical power is supplied to the load 300. Specifically, the control circuit 203 calculates a time (ON time) at which each switching element of the main conversion circuit 201 should enter the ON state based on the electrical power to be supplied to the load 300. For example, the control circuit 203 can control the main conversion circuit 201 by pulse width modulation (PWM) control modulating the ON time of the switching element in accordance with the voltage to be outputted. Then, the control circuit 203 outputs a control command (control signal) to the drive circuit included in the main conversion circuit 201 so that the ON signal is outputted to the switching element which should enter the ON state and the OFF signal is outputted to the switching element which should enter the OFF state at each point of time. The drive circuit outputs the ON signal or the OFF signal as the drive signal to the control electrode of each switching element in accordance with the control signal.

### Method of Manufacturing Power Conversion Apparatus

A method of manufacturing the power conversion apparatus 200 includes the following processes. The semiconductor device 202 is manufactured by the manufacturing method described in the first embodiment, the second embodiment, or a modification example thereof described above. The main conversion circuit 201 including this semiconductor device 202 is formed. The control circuit 203 is formed. The power conversion apparatus 200 is thereby formed. When the main conversion circuit 201 is formed, the back surface electrode 3 of the semiconductor device 10 is bonded to the lead frame 12 via the solder 11, and the front surface electrode 2 is bonded to the lead frame 12 via the wire 13 as illustrated in FIG. 12, for example.

According to the present embodiment, the semiconductor device 202 according to the first embodiment and the second embodiment is used as at least one of the semiconductor device 202 constituting the main conversion circuit 201. Accordingly, a defect caused by the stress from a surrounding member in operation and non-operation of the semiconductor device 202 can be suppressed. Reliability of the main conversion circuit 201 is thereby increased. Thus, reliability of the power conversion apparatus 200 can be increased.

Described in the present embodiment is the example of applying the semiconductor device 202 to the three-phase inverter with two levels. However, the present embodiment is not limited thereto, but can be applied to various power conversion apparatuses. Described in the present embodiment is the power conversion apparatus with two levels, but a power conversion apparatus with three levels or a multilevel power conversion apparatus may also be applied. When electrical power is supplied to a single phase load, the power conversion apparatus described above may be applied to a single-phase inverter. When electrical power is supplied to a direct current load, for example, the power conversion apparatus described above can be applied to a DC/DC converter or an AC/DC converter.

The power conversion apparatus according to the present embodiment can be used not only in the case where the load described above is the electrical motor but can be used as a power source device of an electrical discharge machine, a laser beam machine, an induction heat cooking machine, or a non-contact power supply system, and further can also be used as a power conditioner of a solar power generation system or an electricity storage system, for example.

### Fourth Embodiment

A semiconductor device and a method of manufacturing the semiconductor device according to the present embodiment are described hereinafter.

### Configuration of Semiconductor Device

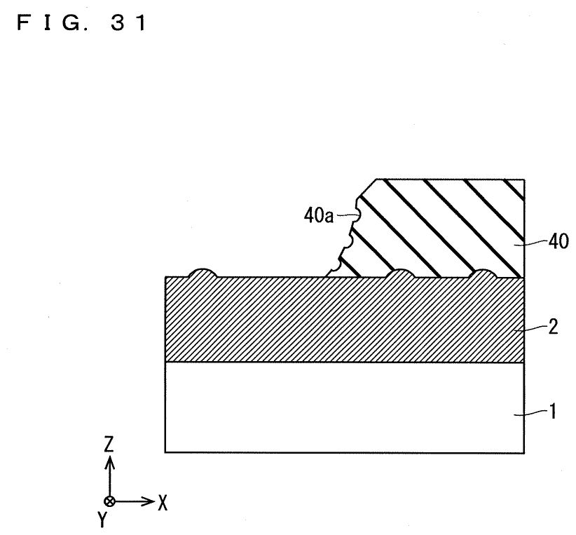

FIG. 1, FIG. 2, and FIG. 31 are diagrams each schematically illustrating an example of a configuration of a semiconductor device manufactured by a manufacturing method described in the present embodiment. FIG. 1 illustrates an example of an SiC-Schottky barrier diode (SBD).

FIG. 31 is a cross-sectional view corresponding to a region surrounded by a broken line in FIG. 2. A difference from the case illustrated in FIG. 3 is a configuration that a concave part 40a is provided in a side surface part of a protection insulating film 40.

The front surface electrode 2 is formed on the upper surface of the semiconductor substrate 1, and furthermore, the protection insulating film 40 is formed on the upper surface of the front surface electrode 2. An arithmetic average roughness of an upper surface of the protection insulating film 40 is smaller than that of a side surface of the protection insulating film 40. The arithmetic average roughness of side surface of the protection insulating film 40 is smaller than that of the interface between the protection insulating film 40 and the front surface electrode 2 (that is to say, the lower surface of the protection insulating film 40). A plurality of corners are provided to an upper end of the protection insulating film 40.

### Method of Manufacturing Semiconductor Device

FIG. 4 is a flow chart illustrating an example of a process of manufacturing an SiC-SBD according to the present embodiment. In the flow chart illustrated in FIG. 4, the corresponding cross-sectional diagrams in FIG. 5 to FIG. 9 up to the formation of the front surface electrode (Step ST03) are common to the configuration according to the first embodiment, thus the description thereof is omitted.

Subsequently, the protection insulating film 4 (the protection insulating film 40 in the present embodiment) is formed as illustrated in FIG. 10. Polyimide or silicone resin is preferable as a material of the protection insulating film, and the protection insulating film is formed on an outermost periphery on a side of a surface of the SiC-SBD by using spin coating, photolithography, and an etching technique or using an application technique by ink jet (corresponding to Step ST04 in FIG. 4). The protection insulating film 4 (the protection insulating film 40 in the present embodiment) covers a part of the upper surface of the drift layer 7 which is not covered by the front surface electrode 2. The protection insulating film covers a part of the upper surface of the front surface electrode 2.

After the protection insulating film 40 is formed, surface processing is performed by plasma including oxygen and argon using a batch-type plasma processing device, for example, to form the plurality of corners on the upper surface of the protection insulating film 40 and the concave part 40a on the side surface of the protection insulating film 40. Also in the present embodiment, when the plurality of corners are also formed on the upper surface of the protection insulating film 40 on the side of the outer periphery of the semiconductor device and concave-convex portions (the concave part 40a) are formed on the side surface of the protection insulating film 40, reliability is further improved.

Subsequently, obtained is the semiconductor device exemplified in FIG. 1, FIG. 2, and FIG. 31 through the process of thinning (reducing the thickness of) the SiC substrate 5 (corresponding to Step ST05 in FIG. 4) in the manner similar to the first embodiment.

In a case where semiconductor device manufactured in such a manner is assembled into the semiconductor module having the structure illustrated in FIG. 12, when the power cycle test of repeating the conduction state and the non-conduction state of the semiconductor device is performed, the protection insulating film 40 receives the stress due to thermal expansion or thermal shrinkage caused by a difference of a linear expansion coefficient from the mold resin 14 from the side of the upper surface and a difference of a linear expansion coefficient from the front surface electrode 2 from the side of the lower surface.

In such a case, in the present embodiment, the arithmetic average roughness of the upper surface of the protection insulating film 40 is smaller than that of the side surface of the protection insulating film 40, and the arithmetic average roughness of the side surface of the protection insulating film 40 is smaller than that of the interface between the protection insulating film 40 and the front surface electrode 2 (that is to say, the lower surface of the protection insulating film 40). External force applied between the protection insulating film 40 and the front surface electrode 2 in accordance with the stress on the protection insulating film 40 received from the mold resin 14 can be reduced compared with the first embodiment, thus the detachment of the protection insulating film 40 can be suppressed.

### Fifth Embodiment

A semiconductor device and a method of manufacturing the semiconductor device according to the present embodiment are described hereinafter.

### Configuration of Semiconductor Device

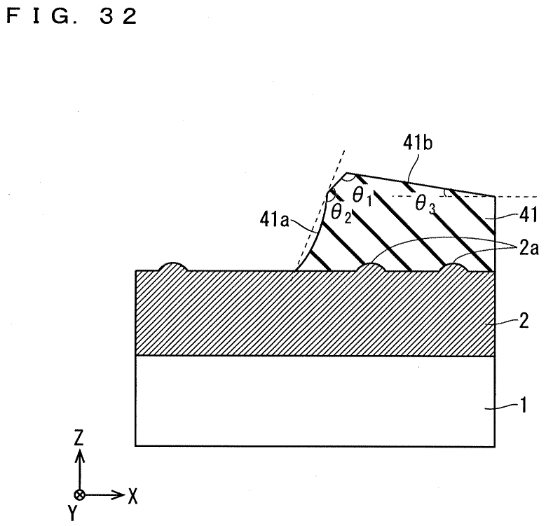

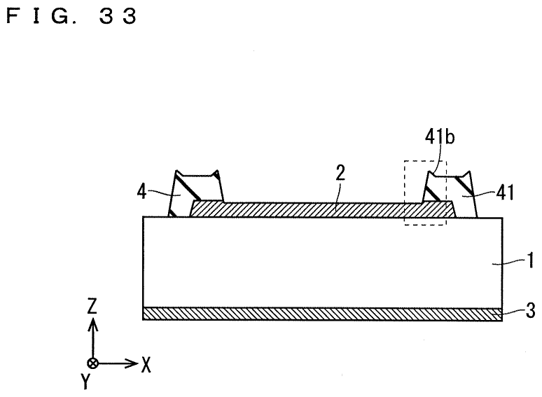

FIG. 1, FIG. 32, and FIG. 33 are diagrams each schematically illustrating an example of a configuration of a semiconductor device manufactured by a manufacturing method described in the present embodiment. FIG. 1 illustrates an example of an SiC-Schottky barrier diode (SBD).

FIG. 32 is a cross-sectional view corresponding to a region surrounded by a broken line in FIG. 33. A difference from the case illustrated in FIG. 3 is a configuration that an inclination part 41b is provided in an upper surface of a protection insulating film 41.

### Method of Manufacturing Semiconductor Device

FIG. 4 is a flow chart illustrating an example of a process of manufacturing an SiC-SBD according to the present embodiment. In the flow chart illustrated in FIG. 4, the corresponding cross-sectional diagrams in FIG. 5 to FIG. 9 up to the formation of the front surface electrode (Step ST03) are common to the configuration according to the first embodiment, thus the description thereof is omitted.

Subsequently, the protection insulating film 4 (the protection insulating film 41 in the present embodiment) is formed as illustrated in FIG. 10. Polyimide or silicone resin is preferable as a material of the protection insulating film, and the protection insulating film is formed on an outermost periphery on a side of a surface of the SiC-SBD by using spin coating, photolithography, and an etching technique or using an application technique by ink jet (corresponding to Step ST04 in FIG. 4). The protection insulating film 4 (the protection insulating film 41 in the present embodiment) covers a part of the upper surface of the drift layer 7 which is not covered by the front surface electrode 2. The protection insulating film covers a part of the upper surface of the front surface electrode 2.

After the protection insulating film 41 is formed, surface processing is performed by plasma including oxygen and argon using a batch-type plasma processing device, for example, to form a plurality of corners on the upper surface of the protection insulating film 41. At that time, when a plurality of corners are also formed on the upper surface of the protection insulating film 41 on a side of an outer periphery of the semiconductor device, reliability is further improved.

Subsequently, thermal processing is performed at a temperature equal to or higher than 250° C. and equal to or lower than 350° C., thus as illustrated in FIG. 32 and FIG. 33, the inclination part 41b having an angle of θ₃ (that is to say, having inclination) with respect to a surface in parallel to the semiconductor substrate (that is to say, the upper surface of the protection insulating film 41) can be provided to the upper surface of the protection insulating film 41.

Subsequently, obtained is the semiconductor device exemplified in FIG. 1, FIG. 32, and FIG. 33 through the process of thinning (reducing the thickness of) the SiC substrate 5 (corresponding to Step ST05 in FIG. 4) in the manner similar to the first embodiment.

In a case where semiconductor device manufactured in such a manner is assembled into the semiconductor module having the structure illustrated in FIG. 12, when the power cycle test of repeating the conduction state and the non-conduction state of the semiconductor device is performed, a thickness of an end portion of the protection insulating film 41 is larger than a center part thereof, thus the end portion of the protection insulating film 41 is deformed by the stress on the semiconductor device received from the mold resin 14, and the stress can be thereby absorbed. Thus, a crack occurring in the protection insulating film 41 can be suppressed.

### Effects Caused by Embodiments Described Above

Examples of effects caused by the above embodiments is described next. It should be noted that, in the following description, the effects are described based on the specific configurations illustrated in the above described embodiments, however, the other specific configurations exemplified in the specification may be applied in place of the configurations, within the scope of producing the similar effects. That is to say, only one of the corresponding specific configurations is representatively described in some cases hereinafter for a purpose of convenience, however, the specific configurations representatively described may be replaced with the other corresponding specific configurations.

Also, the replacement may be implemented with a plurality of embodiments. That is to say, each of the configurations exemplified in the different embodiments may be combined with one another to produce the similar effects.

According to the embodiments described above, the semiconductor device includes the semiconductor layer, the first electrode layer, and the insulating film. Herein, the semiconductor layer corresponds to the drift layer 6 or the drift layer 7, for example. The first electrode layer corresponds to the front surface electrode 2, for example. The insulating film corresponds to the protection insulating film 4, for example. The front surface electrode 2 covers a part of the upper surface of the drift layer 7 via the drift layer 6 and the Schottky electrode layer 9, for example. The protection insulating film 4 covers the other part of the upper surface of the drift layer 7 via the drift layer 6 and the Schottky electrode layer 9, for example. The protection insulating film 4 covers a part of the upper surface of the front surface electrode 2. Herein, the arithmetic average roughness of the upper surface of the protection insulating film 4 is smaller than that of the interface between the protection insulating film 4 and the front surface electrode 2.

According to such a configuration, a contact area having contact with a constituent element on the upper part of the protection insulating film 4 is smaller than that having contact with a constituent element on the lower part of the protection insulating film 4. Thus, connection to the constituent element on the lower part of the protection insulating film 4 is more rigid than connection to the constituent element on the upper part of the protection insulating film 4, thus the detachment of the protection insulating film 4 in operation can be suppressed. According to such a configuration, reliability of the semiconductor device can be increased.

Even in the case where the other configurations exemplified in the specification of the present application is appropriately added to the configuration described above, that is to say, the other configurations other than the configurations in the specification of the present application, which are not referred to as configurations described above are appropriately added, the similar effects can be produced.

According to the embodiments described above, the end portion of the upper surface of the protection insulating film 4 is the inclined surface. Both the corner formed on the upper end of the inclined surface and the corner formed on the lower end of the inclined surface have an obtuse angle. According to such a configuration, the upper and lower ends of the inclined surface have the plurality of corners, thus the stress applied to the protection insulating film 4 from the surrounding part can be dispersed. When the angle of each corner has 90 degrees or more, force applied to the corner can be reduced, thus occurrence of the crack in the protection insulating film 4 can be suppressed.

According to the embodiments described above, the semiconductor device includes the second electrode layer covering a part of the front surface electrode 2. Herein, the second electrode layer corresponds to the front surface electrode 15, for example. The protection insulating film 4 covers a part of the front surface electrode 2. The interface between the front surface electrode 15 and the front surface electrode 2 is located on the lower side than the interface between the protection insulating film 4 and the front surface electrode 2. According to such a configuration, the force on the protection insulating film 4 received from the front surface electrode 15 can be reduced. Thus, the detachment of the protection insulating film 4 can be suppressed.

According to the embodiments described above, the edge line 4a of the side surface of the protection insulating film 4 has the concave shape. According to such a configuration, the occurrence of the crack in the protection insulating film 4 can be suppressed.

According to the embodiments described above, the configuration includes the semiconductor device described above, and further includes the main conversion circuit 201 converting the inputted electrical power and outputting the converted electrical power and the control circuit 203 outputting the control signal for controlling the main conversion circuit 201 to the main conversion circuit 201. According to such a configuration, a contact area having contact with a constituent element on the upper part of the protection insulating film 4 is smaller than that having contact with a constituent element on the lower part of the protection insulating film 4. Thus, connection to the constituent element on the lower part of the protection insulating film 4 is more rigid than connection to the constituent element on the upper part of the protection insulating film 4, thus the detachment of the protection insulating film 4 in operation can be suppressed. According to such a configuration, reliability of the power conversion apparatus including the semiconductor device can be increased.

According to the embodiments described above, a part of the upper surface of the drift layer 6 is covered to form the front surface electrode 2 in the method of manufacturing the semiconductor device. Then, the other part of the upper surface of the drift layer 6 and at least a part of the upper surface of the front surface electrode 2 are covered to form the protection insulating film 4. Herein, the arithmetic average roughness of the upper surface of the protection insulating film 4 is smaller than that of the interface between the protection insulating film 4 and the front surface electrode 2.

According to such a configuration, a contact area having contact with a constituent element on the upper part of the protection insulating film 4 is smaller than that having contact with a constituent element on the lower part of the protection insulating film 4. Thus, connection to the constituent element on the lower part of the protection insulating film 4 is more rigid than connection to the constituent element on the upper part of the protection insulating film 4, thus the detachment of the protection insulating film 4 in operation can be suppressed. According to such a configuration, reliability of the semiconductor device can be increased.

According to the embodiments described above, in the method of manufacturing the power conversion apparatus, the configuration includes the semiconductor device manufacture by the manufacturing method described above, and the main conversion circuit 201 converting the inputted electrical power and outputting the converted electrical power. Then, provided is the control circuit 203 outputting the control signal for controlling the main conversion circuit 201 to the main conversion circuit 201. According to such a configuration, a contact area having contact with a constituent element on the upper part of the protection insulating film 4 is smaller than that having contact with a constituent element on the lower part of the protection insulating film 4. Thus, connection to the constituent element on the lower part of the protection insulating film 4 is more rigid than connection to the constituent element on the upper part of the protection insulating film 4, thus the detachment of the protection insulating film 4 in operation can be suppressed. According to such a configuration, a defect caused by the stress from a surrounding member in operation and non-operation of the semiconductor device can be suppressed. Reliability of the main conversion circuit is thereby increased, and reliability of the power conversion apparatus can be increased.

### Modification Example in Embodiments Described Above

In the embodiments described above, material properties, materials, dimensions, shapes, relative arrangement relations, or conditions for implementation, for example, for the respective constituent elements may be described, however, these represent one example in all aspects, and are not a limited matter.

Accordingly, numerous other modifications variations, and equivalents are devised within the scope of the technique disclosed in the specification of the present application. For example, the following cases where at least one of the constituent elements is to be modified, added, or omitted, further, at least one of the constituent elements of at least one of the embodiments is extracted and then combined with constituent elements of the other embodiment, are involved.

Further, in at least one of the embodiments described above, when names of materials are stated unless otherwise specified, an alloy of the material and other additives, and so forth are included, so far as consistent with the embodiments.

When there is a description that “one” constituent element is included in the embodiments described above, “one or more” constituent elements can be included so far as consistent with the embodiments.

Further, each constituent element in the embodiments described above is a conceptual unit. Thus, within the range of the technique disclosed in the specification of the present application, one constituent element may include multiple structures, one constituent element may correspond to part of some structure, and multiple constituent elements may be included in one structure.

Each constituent element in the embodiments described above includes a structure having a different configuration or a different shape as long as the structure of the different configuration or the different shape achieves the same function.

What has been described in the specification of the present application is referred for all purposes regarding the present technique. It is thus not an admission that any of the descriptions provided herein are conventional techniques.

The aspects of the present disclosure are collectively described hereinafter as appendixes.

### Appendix 1

A semiconductor device, comprising:
a semiconductor layer;
a first electrode layer covering a part of an upper surface of the semiconductor layer; and
an insulating film covering another part of the upper surface of the semiconductor layer and a part of an upper surface of the first electrode layer, wherein
an arithmetic average roughness of an upper surface of the insulating film is smaller than an arithmetic average roughness of an interface between the insulating film and the first electrode layer.

### Appendix 2

The semiconductor device according to Appendix 1, wherein
an end portion of the upper surface of the insulating film is an inclined surface, and
both a corner formed on an upper end of the inclined surface and a corner formed on a lower end of the inclined surface have an obtuse angle.

### Appendix 3

The semiconductor device according to Appendix 1 or 2, wherein
the insulating film covers a part of the first electrode layer,
the semiconductor device further includes a second electrode layer covering a part of the first electrode layer, and
an interface between the second electrode layer and the first electrode layer is located on a lower side than an interface between the insulating film and the first electrode layer.

### Appendix 4

The semiconductor device according to any one of Appendixes 1 to 3, wherein
an edge line of a side surface of the insulating film has a concave shape.

### Appendix 5

A power conversion apparatus, comprising:
a main conversion circuit including the semiconductor device according to any one of Appendixes 1 to 4, converting electrical power which has been input, and outputting the electrical power; and
a control circuit outputting a control signal for controlling the main conversion circuit to the main conversion circuit.

### Appendix 6

A method of manufacturing a semiconductor device, comprising:
covering a part of an upper surface of a semiconductor layer to form a first electrode layer, and
covering another part of the upper surface of the semiconductor layer and at least a part of an upper surface of the first electrode layer to form an insulating film, wherein
an arithmetic average roughness of an upper surface of the insulating film is smaller than an arithmetic average roughness of an interface between the insulating film and the first electrode layer.

### Appendix 7

A semiconductor device, comprising:
a semiconductor layer;
a first electrode layer covering a part of an upper surface of the semiconductor layer; and
an insulating film covering another part of the upper surface of the semiconductor layer and a part of an upper surface of the first electrode layer, wherein
an arithmetic average roughness of an upper surface of the insulating film is smaller than an arithmetic average roughness of a side surface of the insulating film, and
an arithmetic average roughness of a side surface of the insulating film is smaller than an arithmetic average roughness of an interface between the insulating film and the first electrode layer.

### Appendix 8

A method of manufacturing a semiconductor device, comprising:
a semiconductor layer:
a first electrode layer covering a part of an upper surface of the semiconductor layer: and
an insulating film covering another part of the upper surface of the semiconductor layer and a part of an upper surface of the first electrode layer, wherein
an arithmetic average roughness of an upper surface of the insulating film is smaller than an arithmetic average roughness of a side surface of the insulating film, and
an arithmetic average roughness of a side surface of the insulating film is smaller than an arithmetic average roughness of an interface between the insulating film and the first electrode layer.

### Appendix 9

The semiconductor device according to any one of Appendixes 1 to 4 and 7, wherein
an inclination part inclined with respect to the upper surface of the insulating film is provided to the upper surface of the insulating film.

### EXPLANATION OF REFERENCE SIGNS

1 semiconductor substrate, 2 front surface electrode, 2a convex part, 3 back surface electrode, 4 protection insulating film, 4a edge line, 5 substrate, 6 drift layer, 7 drift layer, 8 interlayer insulating film, 9 Schottky electrode layer, 10 semiconductor device, 11 solder, 12 lead frame, 13 wire, 14 mold resin, 15 front surface electrode, 40 protection insulating film, 40a concave part, 41 protection insulating film, 41b inclination part, 100 power source, 200 power conversion apparatus, 201 main conversion circuit, 202 semiconductor device, 203 control circuit, 300 load, 401 average line.

1. A semiconductor device, comprising:
a semiconductor layer;
a first electrode layer covering a part of an upper surface of the semiconductor layer; and
an insulating film covering another part of the upper surface of the semiconductor layer and a part of an upper surface of the first electrode layer, wherein
an arithmetic average roughness of an upper surface of the insulating film is smaller than an arithmetic average roughness of an interface between the insulating film and the first electrode layer.

2. The semiconductor device according to claim 1, wherein
an end portion of the upper surface of the insulating film is an inclined surface, and
both a corner formed on an upper end of the inclined surface and a corner formed on a lower end of the inclined surface have an obtuse angle.

3. The semiconductor device according to claim 1, wherein
the insulating film covers a part of the first electrode layer,
the semiconductor device further includes a second electrode layer covering a part of the first electrode layer, and
an interface between the second electrode layer and the first electrode layer is located on a lower side than an interface between the insulating film and the first electrode layer.

4. The semiconductor device according to claim 1, wherein
an edge line of a side surface of the insulating film has a concave shape.

5. A power conversion apparatus, comprising:
a main conversion circuit including the semiconductor device according to claim 1, converting electrical power which has been input, and outputting the electrical power; and
a control circuit outputting a control signal for controlling the main conversion circuit to the main conversion circuit.

6. A method of manufacturing a semiconductor device, comprising:
covering a part of an upper surface of a semiconductor layer to form a first electrode layer; and
covering another part of the upper surface of the semiconductor layer and at least a part of an upper surface of the first electrode layer to form an insulating film, wherein
an arithmetic average roughness of an upper surface of the insulating film is smaller than an arithmetic average roughness of an interface between the insulating film and the first electrode layer.

7-8. (canceled)

9. The semiconductor device according to claim 1, wherein
an inclination part inclined with respect to the upper surface of the insulating film is provided to the upper surface of the insulating film.

10. A semiconductor device, comprising:
a semiconductor layer;
a first electrode layer covering a part of an upper surface of the semiconductor layer; and
an insulating film covering another part of the upper surface of the semiconductor layer and a part of an upper surface of the first electrode layer, wherein
an arithmetic average roughness of an upper surface of the insulating film is smaller than an arithmetic average roughness of a side surface of the insulating film.

11. The semiconductor device according to claim 10, wherein
an arithmetic average roughness of a side surface of the insulating film is smaller than an arithmetic average roughness of an interface between the insulating film and the first electrode layer.

12. The method of manufacturing the semiconductor device according to claim 6, wherein
an arithmetic average roughness of an upper surface of the insulating film is smaller than an arithmetic average roughness of a side surface of the insulating film, and
an arithmetic average roughness of a side surface of the insulating film is smaller than an arithmetic average roughness of an interface between the insulating film and the first electrode layer.

13. The semiconductor device according to claim 10, wherein
the insulating film covers a part of the first electrode layer,
the semiconductor device further includes a second electrode layer covering a part of the first electrode layer, and
an interface between the second electrode layer and the first electrode layer is located on a lower side than an interface between the insulating film and the first electrode layer.

14. The semiconductor device according to claim 10, wherein
an edge line of a side surface of the insulating film has a concave shape.

15. A power conversion apparatus, comprising:
a main conversion circuit including the semiconductor device according to claim 10, converting electrical power which has been input, and outputting the electrical power; and
a control circuit outputting a control signal for controlling the main conversion circuit to the main conversion circuit.

16. The semiconductor device according to claim 10, wherein
an inclination part inclined with respect to the upper surface of the insulating film is provided to the upper surface of the insulating film.
